(19) United States
(12) Patent Application Publication
(10) Pub. No.: US 2026/0037433 A1
(43) Pub. Date: Feb. 5, 2026

(54) STORAGE DEVICE AND METHOD OF OPERATING THE STORAGE DEVICE ACCORDING TO CHARGING

(71) Applicant: SK hynix Inc., Gyeonggi-do (KR)

(72) Inventor: In Jong JANG, Gyeonggi-do (KR)

(21) Appl. No.: 19/218,385

(22) Filed: May 26, 2025

(30) Foreign Application Priority Data
Aug. 2, 2024 (KR) 10-2024-0103101

(51) Int. Cl. G06F 12/02

(52) U.S. Cl. CPC G06F 12/0246; G06F 2212/7202

(57) ABSTRACT

Provided herein may be a storage device and a method of operating the storage device according to battery charging. The storage device may include a battery configured to supply power, a memory device including first blocks and second blocks, the first blocks programmed when the battery is in an uncharged state of being disconnected from a charging device, the second blocks on which a program operation is to be performed when the battery is in a charged state of being supplied with power from the charging device, and a memory controller configured to control operations performed in the memory device based on determining whether the battery is charged, and open the second blocks in response to the battery changing from the uncharged state to the charged state.

### CROSS-REFERENCE TO RELATED APPLICATION

The present application claims priority under 35 U.S.C. § 119(a) to Korean patent application number 10-2024-0103101 filed on Aug. 2, 2024, the entire disclosure of which is incorporated by reference herein.

### BACKGROUND

### 1. Field of Invention

Various embodiments of the present disclosure generally relate to a storage device, and more particularly to a storage device and a method of operating the storage device according to charging.

### 2. Description of Related Art

A storage device may store data under the control of a host device, such as a computer or a smartphone. A storage device may include a memory device in which data is stored and a memory controller which controls the memory device. Memory devices are classified into a volatile memory device and a nonvolatile memory device. The volatile memory device is a memory device in which data is stored only when power is supplied and in which stored data is lost when the supply of power is interrupted. The nonvolatile memory device is a memory device in which stored data is retained even when the supply of power is interrupted.

The mobility of a storage device for receiving power from a battery may be improved. The power stored in the battery is limited, and thus the battery requires to be charged. Depending on whether the battery is charged, a usage pattern of the storage device may differ. For example, when the battery is being charged, there is no limit on power consumption to allow more operations to be performed in the storage device.

The usage pattern changing according to whether the battery is charged is used to adjust operations performed in the storage device. Therefore, the performance of the storage device may be improved.

### SUMMARY

Various embodiments of the present disclosure are directed to a storage device for opening additional memory blocks to perform operations during charging of a battery and a method of operating the storage device. An embodiment of the present disclosure may provide for a storage

device. The storage device may include a battery configured to supply power, a memory device including first blocks and second blocks, the first blocks programmed when the battery is in an uncharged state of being disconnected from a charging device, the second blocks on which a program operation is to be performed when the battery is in a charged state of being supplied with power from the charging device, and a memory controller configured to control operations performed in the memory device based on determining whether the battery is charged, and open the second blocks in response to changing of the battery from the uncharged state to the charged state.

An embodiment of the present disclosure may provide for a method of operating a storage device. The method may include receiving first charge state information indicating that a battery for supplying power is being charged, controlling charge blocks to be open, the charge blocks on which a program operation is to be performed when the battery is being charged among closed memory blocks included in a memory device based on the first charge state information, generating a charge map table corresponding to the charge blocks, and performing operations on the charge blocks.

### BRIEF DESCRIPTION OF THE DRAWINGS

FIG. 1 is a diagram illustrating a storage device according to an embodiment of the present disclosure.

FIG. 2 is a diagram illustrating the operations of a storage device according to battery charging according to an embodiment of the present disclosure.

FIG. 3 is a diagram illustrating a unit of protocol information for the start or end of charging according to an embodiment of the present disclosure.

FIG. 4 is a diagram illustrating open memory blocks according to the start and end of charging according to an embodiment of the present disclosure.

FIG. 5 is a diagram illustrating an access priority of a map table according to the start and end of charging according to an embodiment of the present disclosure.

FIG. 6 is a diagram illustrating parameters of background operations according to an embodiment of the present disclosure.

FIG. 7 is a flowchart illustrating a method of operating a storage device according to an embodiment of the present disclosure.

FIG. 8 is a flowchart illustrating a method for adjusting the temperature of a memory device according to an embodiment of the present disclosure.

### DETAILED DESCRIPTION

Specific structural or functional descriptions in embodiments according to the concept of the present disclosure, introduced in the present specification, are only for description of the embodiments of the present disclosure. The embodiments according to the concept of the present disclosure may be implemented in various forms, and should not be construed as being limited to the embodiments described in the specification.

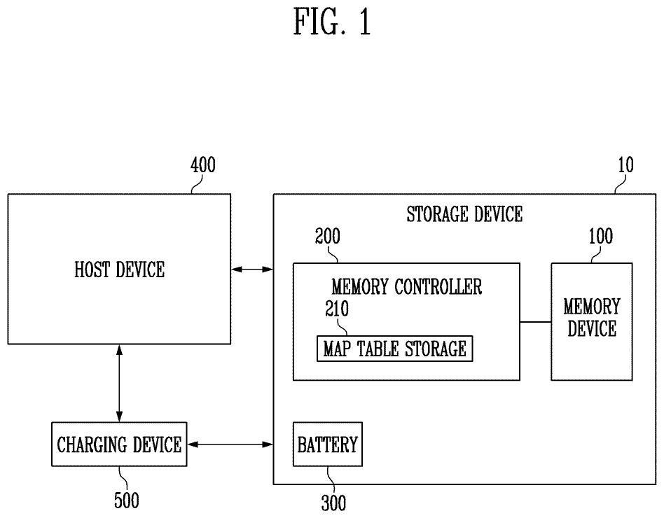

FIG. 1 is a diagram illustrating a storage device 10 according to an embodiment of the present disclosure.

Referring to FIG. 1, the storage device 10 may include a memory device 100, a memory controller 200 which controls the operation of the memory device 10, and a battery 300 which supplies power. The storage device 10 may store data under the control of a host device 400, such as a mobile phone, a smartphone, an MP3 player, a laptop computer, a desktop computer, a game console, a television (TV), a tablet PC, or an in-vehicle infotainment system.

The storage device 10 may be manufactured as any of various types of storage devices according to a communication method with the host device 400. For example, the storage device 10 may be implemented as one of various types of storage devices including a multimedia card in a form of an SSD, an MMC, an eMMC, an RS-MMC, a micro-MMC or the like, a secure digital card in a form of an SD, a mini-SD, a micro-SD or the like, a universal serial bus (USB) storage device, a universal flash storage (UFS) device, a storage device in a form of a peripheral component interconnection (PCI) card, a storage device in a form of a PCI express (PCI-e or PCIe) card, a compact flash (CF) card, a smart media card, a memory stick or the like.

The memory device 100 may store data. The memory device 100 operates in response to a control of the memory controller 200. The memory device 100 may include a plurality of memory blocks. The memory blocks may include a plurality of memory cells for storing data. Memory cells connected to the same word line among the plurality of memory cells may be defined as one physical page.

The memory device 100 may receive a command and an address from the memory controller 200 and access an area selected by the address in a storage area. The memory device 100 may perform an operation instructed by a command on the area selected by the address. For example, the memory device 100 may perform a write operation (a program operation), a read operation, and an erase operation. During the program operation, the memory device 100 may program data into the area selected by the address. During the read operation, the memory device 100 may read data stored in the area selected by the address. During the erase operation, the memory device 100 may erase data stored in the area selected by the address.

The memory controller 200 controls the overall operation of the storage device 10. The memory controller 200 may receive data and a logical address from the host device 400. Further, the memory controller 200 may translate the logical address into a physical address indicating the address of memory cells which are included in the memory device 100 and in which the data is to be stored.

The memory controller 200 may control the memory device 100 so that a program operation, a read operation or an erase operation is performed in response to a request received from the host device 400. During a program operation, the memory controller 200 may provide a write command, a physical address, and data to the memory device 100. During a read operation, the memory controller 200 may provide a read command and a physical address to the memory device 100. During an erase operation, the memory controller 200 may provide an erase command and a physical address to the memory device 100.

The battery 300 may provide power to the storage device 10. The battery 300 may be charged with power provided from the charging device 500. As illustrated in FIG. 1, the battery 300 is positioned inside the storage device 10. Alternatively, the battery 300 may be positioned outside the storage device 10.

The charging device 500 may use a wired charging method and a wireless charging method. The wireless charging method may use the Qi specification of the Wireless Power Consortium (WPC) or the power mat specification of the Power Matters Alliance (PMA).

When the battery 300 is being charged, the power supplied to the storage device 10 may be limitless. When the battery 300 is being charged, an operation speed of the storage device 10 may increase to improve the performance of the storage device 10 even though the power is more consumed than the case of the battery 300 not being charged.

In an embodiment of the present disclosure, the memory controller 200 may control the operations performed in the memory device 100 based on whether the battery 300 is charged. In a first state of the battery 300 being charged, the memory controller 200 may open charge blocks, among a plurality of memory blocks, on which a program operation is to be performed when the battery 300 is being charged.

Some of the plurality of memory blocks included in the memory device 100 may be opened. The program operation may be performed on the open memory blocks. The memory controller 200 may open memory blocks by allocating a buffer for the program operation to the memory blocks. The memory controller 200 may close the open memory blocks by releasing the buffer allocation from the open memory blocks. In an embodiment of the present disclosure, memory blocks to be opened and programmed or programmed memory blocks when the battery 300 is being charged are referred to as charge blocks, and memory blocks to be opened and programmed when the battery 300 is not being charged are referred to non-charge blocks.

The program operation may be performed on additionally open charge blocks in response to charging of the battery 300. The memory controller 200 may control so that background operations for the charge blocks may be performed more frequently than those for the non-charge blocks. The memory controller 200 may store, in the memory device 100, charging information indicating that when the charge blocks are closed, the charge blocks are charge blocks. In an embodiment of the present disclosure, the memory controller 200 may include a map table storage 210. The map table storage 210 may store a map table indicating a mapping relationship between the physical addresses and the logical addresses. The map table storage 210 may store a non-charge map table generated when the battery 300 is not being charged and a charge map table generated when the battery 300 is being charged. The memory controller 200 may change an access priority of the charge map table corresponding to the charge blocks according to whether the battery 300 is charged.

The memory device 100 may include a temperature sensor for measuring the temperature of the memory device 100. The memory controller 200 may generate temperature information indicating the temperature of the memory device 100 based on a measurement of the temperature sensor. The memory controller 200 may adjust the speed of the operations performed in the memory device 100. The higher the temperature of the memory device 100, the faster the operations performed in the memory device 100. The temperature of the memory device 100 may increase due to heat generated when the battery 300 is being charged. The memory controller 200 may adjust the speed of the operations performed in the memory device 100 so that the temperature of the memory device 100 does not exceed a threshold temperature.

Through a signal received from the charging device 500, the host device 400 may determine whether the battery 300 is in a state of being charged. The host device 400 may provide the memory controller 200 with information indicating the start or end of charging of the battery 300. In an embodiment of the present disclosure, the memory controller 200 may receive, from the battery 300, information indicating the start or end of charging of the battery 300.

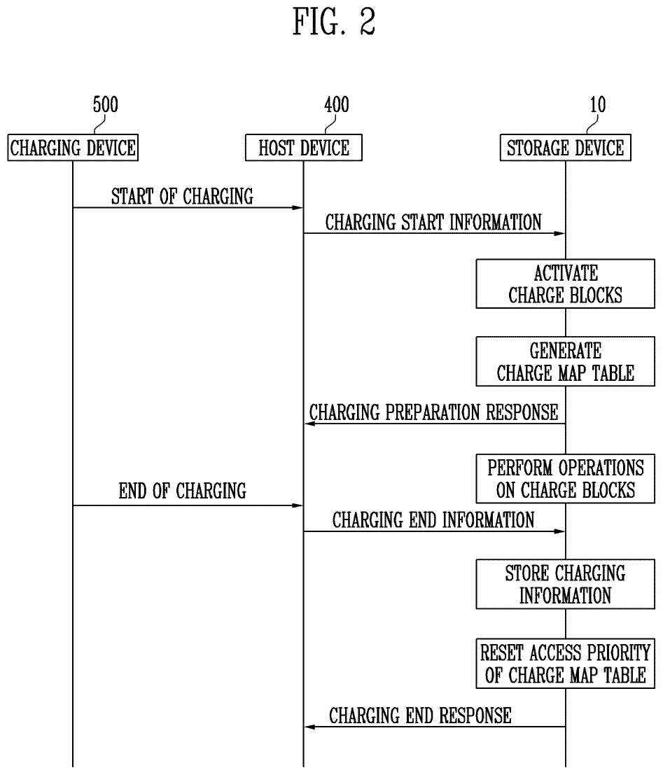

FIG. 2 is a diagram illustrating the operations of the storage device 10 according to battery charging according to an embodiment of the present disclosure.

Referring to FIG. 2, illustrated is a process for performing operations on the additionally open charge blocks according to whether the battery 300 is charged. For convenience, the battery 300 changes from an uncharged state to a charged state, and changes again from the charged state to an uncharged state.

The charging device 500 may provide power to the battery 300. The charging device 500 may transfer, to the host device 400, the signal indicating the start of charging. The host device 400 may transfer charging start information to the storage device 10 based on the received signal. The charging start information indicating the start of charging of the battery 300 may be based on a UFS Protocol Information Unit (UPIU).

The memory controller 200 may additionally open charge blocks among the closed memory blocks based on the charging start information. The memory controller 200 may open memory blocks randomly selected from among the closed memory blocks included in the memory device 100. The number of memory blocks opened when the battery 300 is not being charged may be greater than the number of memory blocks opened when the battery 300 is being charged.

When opening the charge blocks, parameters used for performing the background operations of the charge blocks may be set. The memory controller 200 may set the parameters corresponding to the background operations of the charge blocks so that background operations of the non-charge blocks may be performed more frequently than the background operations of the charge blocks.

The memory controller 200 may generate a charge map table corresponding to the charge blocks in response to opening the charge blocks. The memory controller 200 may store the charge map table in a map table storage 210 in which a non-charge map table corresponding to the non-charge blocks is stored. The memory controller 200 may set the access priority of the charge map table higher than that of the non-charge map table corresponding to the battery 300 being in a charged state.

The memory controller 200 may open the charge blocks, generate the charge map table, and then transmit a charging preparation response to the host device 400. The host device 400 may then transmit commands to be performed on the charge blocks to the memory controller 200 and control the memory device 100 so that operations corresponding to the received commands are performed. When the battery 300 is being charged, the program operations may be performed only on the charge blocks. During charging of the battery 300, the background operations are also included in the operations performed in the memory device 100.

The power supplied to the battery 300 may be off. The charging device 500 may transfer a signal indicating the end of charging to the host device 400. The host device 400 may transfer charging end information to the storage device 10 based on the received signal. Similarly, the charging end information indicating the end of charging of the battery 300 may be based on a UPIU.

In response to the charging end information, the memory controller 200 may close the open charge blocks. The memory controller 200 may store, in the memory device 100, charging information indicating blocks programmed when the battery 300 is being charged. The memory device 100 may store page information indicating a page on which the program operation is performed, and include a dummy space positioned behind a word line on which the program operation is performed. When the charge blocks are closed, the memory controller 200 may store page information indicating a page on which the last program operation is performed or charging information indicating charge blocks being present in the dummy space positioned behind the word line on which the last program operation is performed. The charging information may be a preset data pattern.

In an embodiment of the present disclosure, the memory controller 200 may store, in the memory device 100, page information including charging information. The page information of 4 bytes may be generated for each page of 4 kilo bytes (KB). The page information corresponds to the charge blocks. It may be determined whether the memory block on which the program operation is performed based on the page information is a charge block opened during charging of the battery 300 or a non-charge block opened during non-charging of the battery.

The memory controller 200 may set the access priority of the charge map table lower than that of the non-charge map table corresponding to the battery 300 changing from a charged state to an uncharged state. The access priority of map tables stored in the map table storage 210 may change according to whether the battery 300 is charged. Data programmed during charging of the battery 300 is likely to be re-accessed during charging of the battery 300, and thus the memory controller 200 may set the access priority of the charge map table highest. Similarly, the access priority of the non-charge map table may be set highest when the battery 300 is not being charged.

The memory controller 200 may close the charge blocks, reset the access priority of the map tables, and then transmit a charging end response to the host device 400. Following the charging end response, operations for the non-charge blocks may be performed.

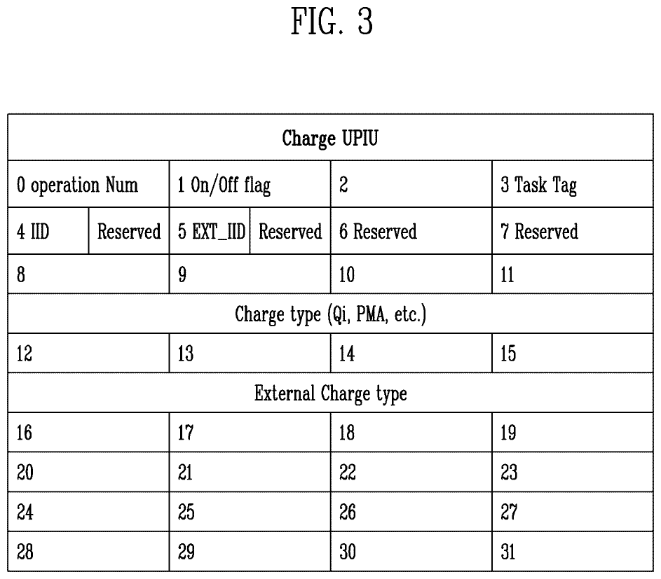

FIG. 3 is a diagram illustrating a unit of protocol information for the start or end of charging according to an embodiment of the present disclosure.

FIG. 3 shows a UPIU representing the charging start information or the charging end information transmitted from the host device 400 to the memory controller 200. The UPIU may be a command.

Referring to FIG. 3, position number 0 of the UPIU may indicate an operation number. The indicated operation may be a program operation, a read operation, or an erase operation. Position number 1 of the UPIU may indicate a charged state of the battery 300. When the battery 300 is being charged, “On” flag may be displayed. Otherwise, “Off” flag may be displayed. Position number 3 may indicate the order of a command corresponding to the operation indicated in position number 0 (i.e., task tag).

Position numbers 8 to 11 of the UPIU may indicate charging types. The charging device 500 may charge the battery 300 in a wired or wireless method. In case of wireless charging, a charging type may be Qi or PMA charging. Position numbers 12 to 15 of the UPIU may indicate an additional charging (external charge) type. The additional charging types may be voltage, current, and power charging, etc.

The UPIU illustrated in FIG. 3 is merely illustrative, and the charging start information or the charging end information transmitted to the storage device 10 may have various formats.

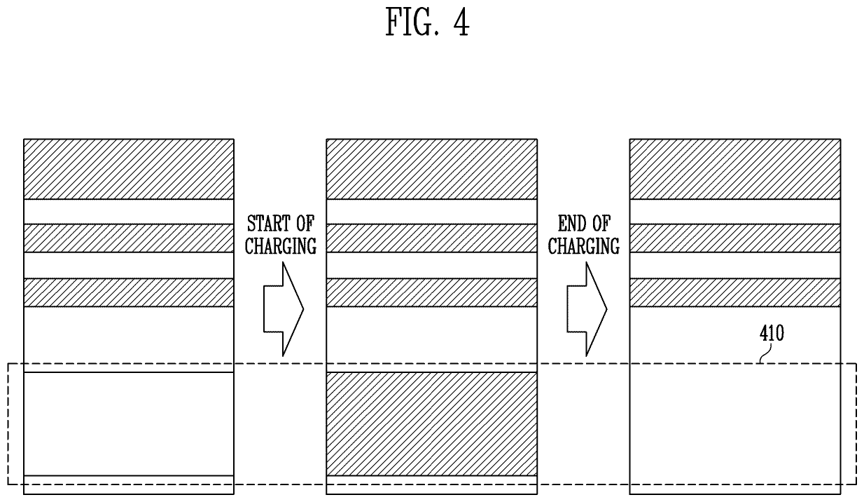

FIG. 4 is a diagram illustrating the open memory blocks according to the start and end of charging according to an embodiment of the present disclosure.

Referring to FIG. 4, the plurality of memory blocks included in the memory device 100 are shown. In FIG. 4, hatched areas are the open memory blocks and the battery 300 changes from an uncharged state to a charged state and changes again to an uncharged state.

When the battery 300 is not in an uncharged state, some of the plurality of memory blocks are opened for program operations. Some open memory blocks are the non-charge blocks. As for the memory device 100 supported with a write booster operation, the non-charge blocks may include a single level cell block, a triple level cell block, a write booster block and a replay protection memory block. The single level cell block may include memory cells for storing one bit per one memory cell. The triple level cell block may include memory cells for storing three bits per one memory cell. The write booster block may temporarily store data during the booster operation. The replay protection memory block stores data requiring security.

When the battery 300 changes to a charged state, the memory controller 200 may additionally open charge blocks among unopened memory blocks. The memory controller 200 may randomly select the unopened memory blocks to open as charge blocks. Reference numeral 410 indicates charge blocks to be opened or closed according to a charge state of the battery 300. The charge blocks are additionally opened when the battery 300 is being charged, and thus the total number of the open memory blocks may increase.

As for the memory device 100 supported with the write booster operation, the host device 400 may instruct whether to allow the write booster operation. The memory controller 200 receiving a signal for instructing the write booster operation from the host device 400 may additionally open a charging-write booster block during charging of the battery 300.

The write booster operation is for temporarily storing data on a memory block with high data storage speed and then moving the data to a memory block with low data storage speed. The amount of data storable per one memory cell is greater in a memory block with low storage speed than in a memory block with high storage speed. The memory device 100 may be efficiently used by increasing the program speed through the write booster operation for temporarily storing data, which is to be programmed in a memory block with low storage speed, in a memory cell with high storage speed.

When charging of the battery 300 ends, the memory controller 200 may close the opened charge blocks. The memory controller 200 may store, in the memory device 100, charging information indicating that the charge blocks at the time of closing are charge blocks programmed at the time of charging. The memory controller 200 may store the charging information in dummy data or page information included in the charge blocks.

The memory blocks described in FIG. 4 are merely illustrative and the types of the opened memory blocks may be various.

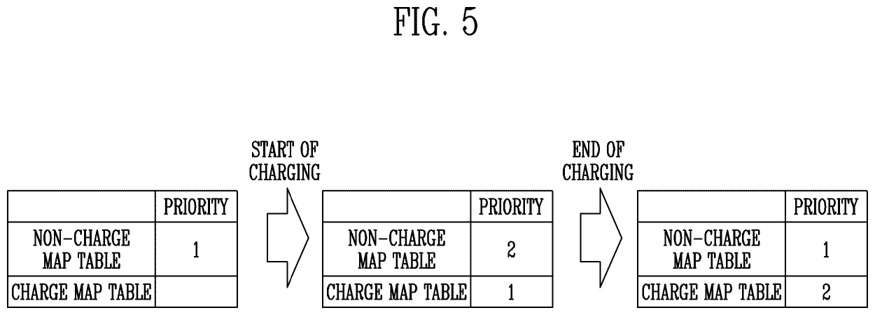

FIG. 5 is a diagram illustrating the priority of map table accesses according to the start and end of charging according to an embodiment of the present disclosure.

Referring to FIG. 5, the access priority of map tables stored in the map table storage 210 is shown. The access priority may be greater as the number of priority is less.

When the battery 300 is not being charged, only the non-charge map table may be stored in the map table storage 210. The access priority of the non-charge map table may be the highest. When receiving a read command or an erase command from the host device 400, the memory controller 200 may use the map table to acquire an address corresponding to the read command or erase command.

When the battery 300 is being charged, the memory controller 200 may generate the charge map table corresponding to the charge blocks. The memory controller 200 may set the access priority of the generated charge map table greater than that of the non-charge map table.

When charging of the battery 300 ends, the memory controller 200 may reset the access priority of the map tables stored in the map table storage 210. The memory controller 200 may set the access priority of the non-charge map table greater than that of the charge map table.

Since the access priority of the map tables is determined differently according to whether the battery 300 is charged, output data may be determined differently even when logical addresses corresponding to read commands received from the host device 400 are the same. For example, the non-charge map table in which physical address 100 is mapped to logical address 0 is stored when the battery 300 is not being charged, the charge map table in which physical address 1 is mapped to logical address 0 is generated when the battery 300 is being charged, and a read command for logical address 0 is received. The access priority of the charge map table is the highest when the battery 300 is being charged, and thus data stored in physical address 1 mapped to logical address 0 is output. The access priority of the non-charge map table is the highest when the battery 300 is not being charged, and thus data stored in physical address 100 mapped to logical address 0 is output.

The memory controller 200 may search for data using a map table having a highest access priority first. Even though the battery 300 is being charged, the memory controller 200 may search for an address to be mapped using the non-charge map table when there is not an address to be mapped to the charge map table.

When charging of the battery 300 ends, the charge blocks are closed, but the charge map table may be maintained in the map table storage 210. Even though the battery 300 is not being charged, the memory controller 200 may search for an address to be mapped using the charge map table when there is not an address to be mapped to the non-charge map table.

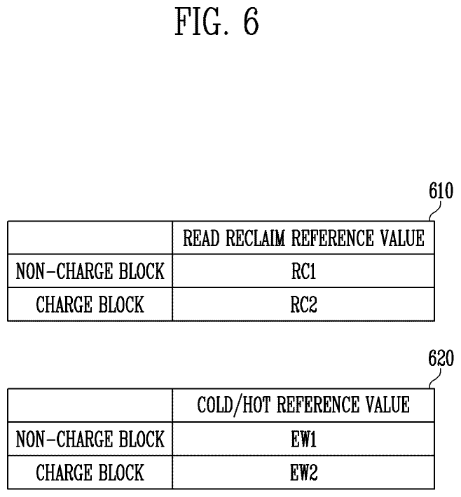

FIG. 6 is a diagram illustrating parameters of background operations according to an embodiment of the present disclosure.

Referring to FIG. 6, the memory controller 200 may set the parameters of the background operations when opening the memory blocks. In FIG. 6, a read reclaim operation and a wear leveling operation are described as examples of the background operations, and the parameters of the background operations may be various.

The memory controller 200 may store the parameters corresponding to the background operations of the non-charge blocks. The memory controller 200 may set parameters used for performing the background operations of the charge blocks in response to opening the charge blocks. The memory controller 200 may set parameters so that the background operations of the charge blocks are more frequently performed than those of the non-charge blocks.

In FIG. 6, the memory controller 200 may store a first read reclaim reference value RC1 in a read reclaim reference value table 610 when opening the non-charge blocks, and store a second read reclaim reference value RC2 in the read reclaim reference value table 610 when opening the charge blocks. The first read reclaim reference value RC1 and the second read reclaim reference value RC2 are read counts.

When the read count of the memory block is greater than the reference value stored in the read reclaim reference value table 610, a read reclaim operation may be performed. The memory controller 200 may set read reclaim reference values so that the second read reclaim reference value RC2 is less than the first read reclaim reference value RC1. When the battery 300 is being charged and the read count of the memory block is greater than the second read reclaim reference value RC2, the read reclaim operation is performed. Since the second read reclaim reference value RC2 is less than the first read reclaim reference value RC1, the read reclaim operation may be more frequently performed in the charge blocks than in the non-charge blocks.

Similarly in FIG. 6, the memory controller 200 may store a first cold and hot (cold/hot) reference value EW1 in a wear leveling reference value table 620 when opening the non-charge blocks, and store a second cold/hot reference value EW2 in the wear leveling value table 620 when opening the charge blocks. The first cold/hot reference value EW1 and the second cold/hot reference value EW2 are erase and write (erase/write) counts.

The memory block is determined to be a hot block or a cold block according to a comparison result between an erase/write count of the memory block and the reference value stored in the wear leveling reference value table 620. The memory block in which the erase/write count is greater than the reference value stored in the wear leveling reference value table 620 is determined to be the hot block. The memory block in which the erase/write count is not greater than (i.e., less than or equal to) the reference value stored in the wear leveling reference value table 620 is determined to be the cold block. The memory controller 200 may set cold/hot reference values so that the second cold/hot reference value EW2 is less than the cold/hot reference value EW1. Even when the erase/write counts are the same, there are more cases in which the memory block is a hot block when the battery 300 is being charged. Accordingly, the wear leveling operation may be more frequently performed than the uncharged state of the battery 300.

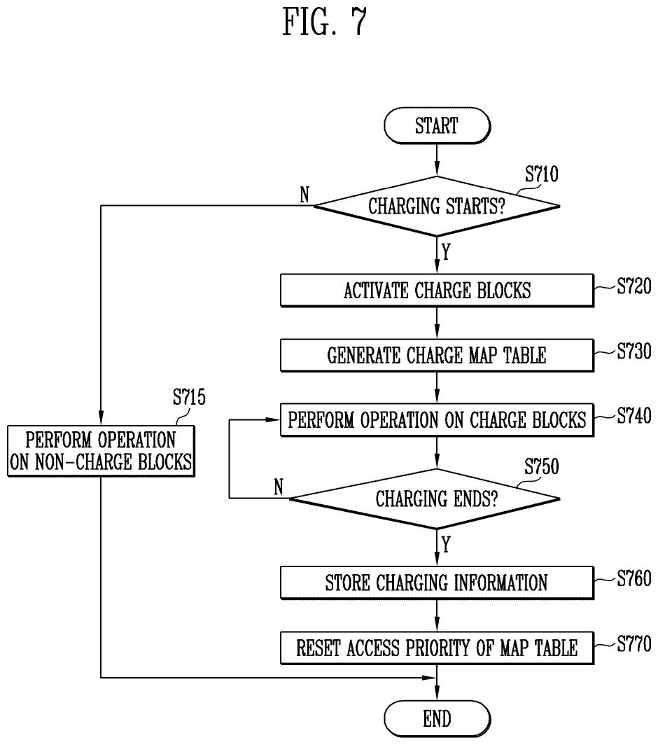

FIG. 7 is a flowchart illustrating a method of operating a storage device 10 according to an embodiment of the present disclosure.

Referring to FIG. 7, the memory controller 200 may additionally open the charge blocks and close the open charge blocks according to whether the battery 300 is charged. The memory controller 200 may generate map tables corresponding to the open memory blocks and adjust the access priority of the map tables. The memory controller 200 may improve the performance of the memory device 100 by adjusting the parameters corresponding to the background operations of the charge blocks so that the background operations are more frequently performed when the battery 300 is being charged. The memory controller 200 may store the charging information indicating that the memory blocks are charge blocks and indicate that the memory blocks have been charge blocks even after charging of the battery 300 ends.

At S710, the memory controller 200 may determine whether the battery 300 is charged. The memory controller 200 may receive first charge state information indicating the charging of the battery 300 from the host device 400. The host device 400 may generate, based on the signal received from the charging device 500, the first charge state information or second charge state information indicating whether the battery 300 is charged. The second charge state information indicates that the battery 300 is not being charged. When it is determined that the battery 300 is in an uncharged state (S710, N), the method proceeds to S715. When it is determined that the battery 300 is in a charged state (S710, Y), the method proceeds to S720.

At S715, the memory device 100 may perform operations on the non-charge blocks. The memory controller 200 may receive, from the host device 400, commands for operations to be performed. The memory controller 200 may control the memory device 100 to perform the operations based on the received commands.

At S720, the memory controller 200 may open charge blocks on which a program operation is to be performed among unopen memory blocks included in the memory device when the battery 300 is being charged. The memory controller 200 may set parameters to be used for performing the background operations of the charge blocks. The memory controller 200 may set the background operations so that the background operations of the charge blocks are more frequently performed than those of the non-charge blocks.

At S730, the memory controller 200 may generate the charge map table corresponding to the charge blocks. The memory controller 200 may set the access priority of the charge map table greater than that of the non-charge map table based on the charging start information.

At S740, the memory device 100 may perform operations on the charge blocks. The memory controller 200 may receive, from the host device 400, commands indicating operations to be performed in the charge blocks. The memory controller 200 may adjust the speed of the operations to be performed on the memory device 100 based on the result of a comparison between the temperature of the memory device 100 and a threshold temperature.

At S750, the memory controller 200 may determine whether the charging of the battery 300 ends. The memory controller 200 may receive second charging state information from the host device 400. When it is determined that the charging of the battery 300 does not end (S750, N), the method may return to S740 and the operations for the charge blocks are performed. When it is determined that the charging of the battery 300 ends (S750, Y), the method proceeds to S760.

At S760, based on the second charging state information, the memory controller 200 may store, in the memory device 100, charging information indicating that the charge blocks were programmed when the battery 300 was being charged. The memory controller 200 may store the charging information in a dummy space included in the charge blocks. In some embodiments, the charging information may have a preset data pattern. The memory controller 200 may store the charging information so that the charging information is included in page information indicating the states of pages included in the charge blocks.

At S770, the memory controller 200 may reset the access priority of the map tables stored in the map table storage 210. The memory controller 200 may set the access priority of the charge map table less than that of the non-charge map table based on the charging end information.

Each of the operations of FIG. 7 may correspond to the descriptions of FIGS. 1 to 6.

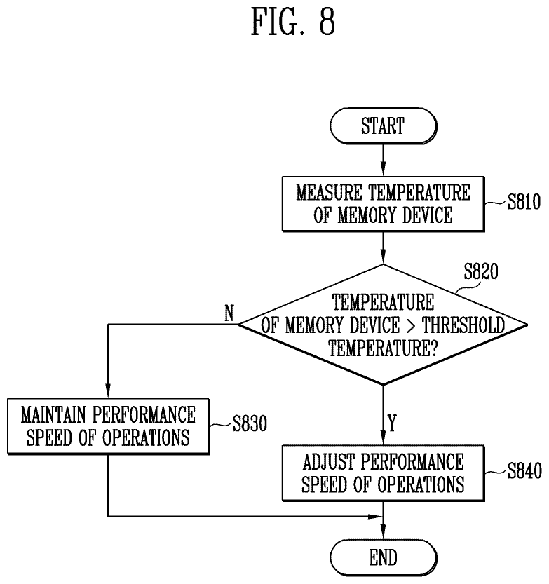

FIG. 8 is a flowchart illustrating a method for adjusting the temperature of a memory device 100 according to an embodiment of the present disclosure.

Referring to FIG. 8, the memory controller 200 may perform a temperature management operation for managing the temperature of the memory device 100 so as not to be greater than the threshold temperature. When the battery 300 is being charged, the temperature of the memory device 100 may increase due to the operations performed in the memory device 100. In addition, heat generated by charging the battery 300 may cause an increase in temperature of the memory device 100.

At S810, a temperature sensor included in the memory device 100 may measure the temperature of the memory device 100. The memory controller 200 may generate temperature information about the memory device 100 based on the measurement of the temperature sensor.

At S820, the memory controller 200 may determine whether the temperature of the memory device 100 is greater than the threshold temperature. When it is determined that the temperature of the memory device 100 is not greater than the threshold temperature (S820, N), the method proceeds to S830. When it is determined that the temperature of the memory device 100 is greater than the threshold temperature (S820, Y), the method proceeds to S840.

The temperature sensor may measure the temperature of the memory device 100 every command timeout time (timeout time of every command) corresponding to the operations performed in the memory device 100. The memory controller 200 may compare the temperature of the memory device 100 with the threshold temperature every command timeout time.

At S830, the memory controller 200 may maintain the speed of the operations performed in the memory device 100. Alternatively, when it is determined that the temperature of the memory device 100 is less than the threshold temperature, the speed of the operations performed in the memory device 100 may increase.

At S840, the memory controller 200 may adjust the speed of the operations performed in the memory device 100. In one embodiment, the memory controller 200 may lower (decrease) the priority of commands instructing the operations to be performed in the memory device 100 in response to the determination that the temperature of the memory device 100 is greater than the threshold temperature. As the priority of the commands is lowered, the speed of the operations performed in the memory device 100 may decrease.

In some embodiments, the memory controller 200 may reduce the clock speed of the memory device 100. In response to the reduction of the clock speed, a command processing speed between the memory controller 200 and the memory device 100 may decrease. In response to the decrease in the command processing speed, the number of operations performed in the memory device 100 for a unit time may be reduced.

The memory controller 200 may reduce a signal transmission and reception speed between the host device 400 and the storage device 10. In response to the reduction of the signal transmission and reception speed, the number of commands received by the memory controller 200 from the host device 400 for a unit time may be reduced.

The memory controller 200 may reduce the number of operations performed in the memory device 100 for a unit time to decrease the temperature of the memory device 100. As the priority of the commands is lowered, the number of operations performed in the memory device 100 for a unit time may be reduced. The reduction in number of operations performed for a unit time may decrease the temperature of the memory device 100. The total number of operations performed in the memory device 100 is maintained regardless of the speed of the operations.

According to the embodiments of the present disclosure, there may be provided a storage device for opening additional memory blocks during charging of the battery to perform the program operations, and a method of operating the storage device.

It should be understood that the scope of the present disclosure is defined by the accompanying claims rather than the detailed description, and all changes or modifications derived from the meaning and scope of the claims and equivalents thereof are included in the scope of the present disclosure. Furthermore, the embodiments may be combined to form additional embodiments.

What is claimed is:

1. A storage device comprising:
a battery configured to supply power;
a memory device including first blocks and second blocks, the first blocks programmed when the battery is in an uncharged state of being disconnected from a charging device, the second blocks on which a program operation is to be performed when the battery is in a charged state of being supplied with power from the charging device; and
a memory controller configured to control operations performed in the memory device based on determining whether the battery is charged, and
open the second blocks in response to the battery changing from the uncharged state to the charged state.

2. The storage device according to claim 1, wherein the memory controller is configured to store a first map table corresponding to the first blocks and to generate a second map table corresponding to the second blocks in response to determining that the second blocks are open.

3. The storage device according to claim 2, wherein the memory controller is configured to set an access priority of the second map table to be greater than an access priority of the first map table in response to the battery changing from the uncharged state to the charged state.

4. The storage device according to claim 3, wherein the memory controller is configured to set an access priority of the first map table to be greater than an access priority of the second map table in response to the battery changing from the charged state to the uncharged state.

5. The storage device according to claim 1, wherein the memory controller is configured to store first parameters used for performing background operations of the first blocks and to set second parameters used for performing background operations of the second blocks in response to determining that the second blocks are open.

6. The storage device according to claim 5, wherein the memory controller is configured to set the second parameters so that the background operations of the second blocks are more frequently performed than the background operations of the first blocks.

7. The storage device according to claim 1, wherein the memory controller is configured to generate temperature information indicating a temperature of the memory device and to control a speed of each of the operations to be decreased in response to determining the temperature of the memory device is greater than a threshold temperature based on the temperature information.

8. The storage device according to claim 7, wherein the memory controller is configured to lower a priority of each command instructing the operations.

9. The storage device according to claim 8, wherein the memory controller is configured to reduce a number of the operations performed for a preset period based on the priority of the commands.

10. The storage device according to claim 1, wherein the memory controller is configured to store, in the memory device, charging information indicating blocks programmed when the battery is in the charged state.

11. The storage device according to claim 10, wherein:
the memory controller is configured to store the charging information in a dummy space included in the second blocks in response to the battery changing from the charged state to the uncharged state, and
the charging information includes a preset data pattern.

12. The storage device according to claim 10, wherein the memory controller is configured to include the charging information in page information indicating states of pages included in the second blocks.

13. A method of operating a storage device, the method comprising:
receiving first charge state information indicating that a battery for supplying power is being charged;
controlling charge blocks to be open, the charge blocks on which a program operation is to be performed when the battery is being charged, among closed memory blocks included in a memory device based on the first charge state information;
generating a charge map table corresponding to the charge blocks; and
performing operations on the charge blocks.

14. The method according to claim 13, wherein:
controlling the charge blocks comprises:
setting parameters used for performing background operations of the charge blocks so that the background operations of the charge blocks are more frequently performed than background operations of non-charge blocks opened when the battery is not being charged.

15. The method according to claim 13, wherein generating the charge map table comprises:
setting, based on the first charged state information, an access priority of the charge map table to be greater than an access priority of a non-charge map table generated when the battery is not being charged.

16. The method according to claim 13, wherein performing the operations comprises:
adjusting a speed of each of the operations based on a result of a comparison between a temperature of the memory device and a threshold temperature.

17. The method according to claim 16, wherein adjusting the speed of each of the operations comprises:
lowering a priority of each command instructing the operations to be performed in response to determining the temperature of the memory device is greater than the threshold temperature.

18. The method according to claim 13, further comprising:
receiving second charge state information indicating end of charging the battery;
storing, in the memory device, charging information indicating blocks programmed when the battery is being charged, based on the second charging state information; and
resetting access priority of the charge map table.

19. The method according to claim 18, wherein:
storing the charging information comprises:
storing the charging information in a dummy space included in the charge blocks, and
the charging information includes a preset data pattern.

20. The method according to claim 18, wherein storing the charging information comprises:
storing the charging information so that the charging information is included in page information indicating states of pages included in the charge blocks.

21. The method according to claim 18, wherein resetting the access priority of the charge map table comprises:
setting, based on the second charge state information, the access priority of the charge map table to be lower than an access priority of a non-charge map table generated when the battery is not being charged.
